(19) United States
(12) Patent Application Publication
(10) Pub. No.: US 2007/0284583 A1
(43) Pub. Date: Dec. 13, 2007

(54) Semiconductor device and method of manufacturing the same

(75) Inventor: Tomohiro Saito, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba

(21) Appl. No.: 11/882,618

(22) Filed: Aug. 3, 2007

Related U.S. Application Data
(62) Division of application No. 10/796,183, filed on Mar. 10, 2004.

(30) Foreign Application Priority Data
Oct. 3, 2003 (JP) 2003-345956

(51) Int. Cl. H01L 29/78

(52) U.S. Cl. 257/66; 257/E29.264; 257/E29.003

(57) ABSTRACT

A method of manufacturing a semiconductor device, including forming a gate electrode or dummy gate on a fin-type silicon layer, introducing an impurity into the fin-type silicon layer with the gate electrode or dummy gate used as mask so as to form first impurity regions, etching the gate electrode or dummy gate so as to form a gate electrode or dummy gate having a reduced size, and introducing an impurity into the fin-type silicon layer with the gate electrode or dummy gate of the reduced size used as a mask so as to form second impurity regions positioned adjacent to the first impurity diffusion regions.

### CROSS-REFERENCE TO RELATED APPLICATIONS

This application is based upon and claims the benefit of priority from prior Japanese Patent Application No. 2003-345956, filed Oct. 3, 2003, the entire contents of which are incorporated herein by reference.

### BACKGROUND OF THE INVENTION

1. Field of the Invention

The present invention relates to a semiconductor device and a method of manufacturing the same, particularly, to a fin-type field-effect semiconductor device of a three-dimensional structure and a method of manufacturing the same.

2. Description of the Related Art

With progress in the miniaturization of a silicon semiconductor transistor, a fin-type field-effect transistor of a three-dimensional structure has come to be studied in place of the conventional planar transistor. The fin-type field-effect transistor is a double-gate-type field-effect transistor in which channels are formed on both sides of a projecting silicon layer and can be manufactured by the method described in, for example, Japanese Patent Disclosure No. 2002-110963.

It should be noted in this connection that, in forming the source and drain regions in the manufacturing method described in the prior art referred to above, a gate electrode is formed first, followed by applying ion implantation into an extended portion, e.g., an LDD region. Then, side walls are formed in the side wall portions of the gate electrode, followed by applying ion implantation in a concentration higher than that in the LDD region so as to form the source and drain region as in the manufacturing method of the ordinary planar transistor. According to the manufacturing method described in the prior art referred to above, however, an inconvenience is brought about in forming source and drain diffusion regions, as pointed out below.

Specifically, if an insulating film is formed on the side wall of the gate electrode after formation of the gate electrode in the fin-type field-effect transistor, a side wall insulating film is formed simultaneously on the side surfaces of those portions of the fin-type silicon layer in which the source and drain diffusion regions and the channels are to be formed, with the result that it is impossible to carry out ion implantation for forming the source and drain regions.

### BRIEF SUMMARY OF THE INVENTION

According to a first aspect of the present invention, there is provided a method for manufacturing a semiconductor device, comprising: forming a mask material on a silicon layer on a surface of a semiconductor substrate; patterning the silicon layer with the mask material used as a mask so as to form a fin-type silicon layer having the mask material formed on the surface; forming a gate insulating film on side surfaces of the fin-type silicon layer; depositing a gate material on an entire surface; patterning the gate material layer so as to form a gate electrode; introducing an impurity into the fin-type silicon layer with the gate electrode used as mask so as to form first impurity regions; etching the gate electrode so as to form a gate electrode having a reduced size; and introducing an impurity into the fin-type silicon layer with the gate electrode of the reduced size used as a mask so as to form second impurity regions positioned adjacent to the first impurity diffusion regions.

According to a second aspect of the present invention, there is provided a method of manufacturing a semiconductor device, comprising: forming a mask material on a silicon layer on a surface of a semiconductor substrate; patterning the silicon layer with the mask material used as a mask so as to form a fin-type silicon layer having the mask material formed on the surface; forming a gate insulating film on side surfaces of the fin-type silicon layer; depositing a gate material on an entire surface; planarizing the gate material so as to expose the mask material to outside; patterning the gate material layer so as to form a gate electrode; introducing an impurity into the fin-type silicon layer with the gate electrode used as mask so as to form first impurity regions; etching the gate electrode so as to form a gate electrode having a reduced size; and introducing an impurity into the fin-type silicon layer with the gate electrode of the reduced size used as a mask so as to form second impurity regions positioned adjacent to the first impurity diffusion regions.

According to a third aspect of the present invention, there is provided a method of manufacturing a semiconductor device, comprising: forming a mask material on a silicon layer on a surface of a semiconductor substrate; patterning the silicon layer with the mask. material used as a mask so as to form a fin-type silicon layer having the mask material formed on the surface; forming a gate insulating film on side surfaces of the fin-type silicon layer; depositing a gate material on an entire surface; planarizing the gate material so as to expose the mask material to outside; depositing a second gate material on an entire surface; patterning the first and second gate material layers so as to form a gate electrode; introducing an impurity into the fin-type silicon layer with the gate electrode used as mask so as to form first impurity regions; etching the gate electrode so as to form a gate electrode having a reduced size; and introducing an impurity into the fin-type silicon layer with the gate electrode of the reduced size used as a mask so as to form second impurity regions positioned adjacent to the first impurity diffusion regions.

According to a fourth aspect of the present invention, there is provided a method of manufacturing a semiconductor device, comprising: forming a mask material on a silicon layer on a surface of a semiconductor substrate; patterning the silicon layer with the mask material used as a mask so as to form a fin-type silicon layer having the mask material formed on the surface; forming a buffer layer on side surfaces of the fin-type silicon layer; forming a dummy gate material on an entire surface; planarizing the dummy gate material layer so as to expose the mask material layer to outside; patterning the dummy gate material layer so as to form a dummy gate; introducing an impurity into the fin-type silicon layer with the dummy gate used as a mask so as to form first impurity regions; etching the dummy gate so as to form a dummy gate having a reduced size; introducing an impurity into the fin-type silicon layer with the dummy gate having a reduced size used as a mask so as to form second impurity regions positioned adjacent to the first impurity regions; forming an interlayer insulating film on an entire surface; planarizing a surface of the interlayer insulating film so as to expose the dummy gate; removing the dummy gate and the buffer layer so as to form a gate groove; forming a gate insulating film on an inner surface of the gate groove; and forming a gate electrode within the gate groove.

According to a fifth aspect of the present invention, there is provided a method of manufacturing a semiconductor device, comprising: forming a mask material on a silicon layer on a surface of a semiconductor substrate; patterning the silicon layer with the mask material used as a mask so as to form a fin-type silicon layer having the mask material formed on the surface; forming a buffer layer on side surfaces of the fin-type silicon layer; depositing a first dummy gate material on an entire surface; planarizing the first dummy gate material layer so as to expose the mask material layer to outside; depositing a second dummy gate material on an entire surface; patterning the first and second dummy gate material layers so as to form a dummy gate; introducing an impurity into the fin-type silicon layer with the dummy gate used as a mask so as to form first impurity regions; etching the dummy gate so as to form a dummy gate having a reduced size; introducing an impurity into the fin-type silicon layer with the dummy gate having a reduced size used as a mask so as to form second impurity regions positioned adjacent to the first impurity regions; forming an interlayer insulating film on an entire surface; planarizing a surface of the interlayer insulating film so as to expose the dummy gate; removing the dummy gate and the buffer layer so as to form a gate groove; forming a gate insulating film on an inner surface of the gate groove; and forming a gate electrode within the gate groove.

According to a sixth aspect of the present invention, there is provided a semiconductor device, comprising: a fin-type silicon layer formed on a semiconductor substrate; a mask material formed on the fin-type silicon layer; a gate insulating film and a gate electrode formed in contact with side surfaces of the fin-type silicon layer and the mask material; first impurity regions formed a prescribed distance apart from a region corresponding to the gate electrode of the fin-type silicon layer; and second impurity regions formed between the first impurity regions of the fin-type silicon layer and the region corresponding to the gate electrode.

According to a seventh aspect of the present invention, there is provided a semiconductor device, comprising: a fin-type silicon layer formed on a semiconductor substrate; a gate insulating film and a gate electrode formed in contact with side surfaces and upper surface of the fin-type silicon layer; first impurity regions formed a prescribed distance apart from a region corresponding to the gate electrode of the fin-type silicon layer; and second impurity regions formed between the first impurity regions of the fin-type silicon layer and the region corresponding to the gate electrode.

According to an eighth aspect of the present invention, there is provided a semiconductor device, comprising: a fin-type silicon layer formed on a semiconductor substrate and having first and second side surfaces; a mask material formed on the fin-type silicon layer; a first gate insulating film and a first gate electrode formed in contact with the first side surface of the fin-type silicon layer; a second gate insulating film and a second gate electrode formed in contact with the second side surface of the fin-type silicon layer; first impurity regions formed a prescribed distance apart from a region corresponding to the first and second gate electrodes of the fin-type silicon layer; and second impurity regions formed between the first impurity regions of the fin-type silicon layer and the region corresponding to the first and second gate electrodes.

According to a ninth aspect of the present invention, there is provided a semiconductor device, comprising: a fin-type silicon layer formed on a semiconductor substrate and having first and second side surfaces; a mask material formed on the fin-type silicon layer; a first gate insulating film and a first gate electrode formed in contact with the first side surface of the fin-type silicon layer; a second gate insulating film and a second gate electrode formed in contact with the second side surface of the fin-type silicon layer; a third gate electrode formed in contact with upper surfaces of the first gate electrode and the second gate electrode; first impurity regions formed a prescribed distance apart from a region corresponding to the first, second and third gate electrodes of the fin-type silicon layer; and second impurity regions formed between the first impurity region of the fin-type silicon layer and the region corresponding to the first, second and third gate electrodes.

### BRIEF DESCRIPTION OF THE SEVERAL VIEWS OF THE DRAWING

FIGS. 1A, 1B, 2A, 2B, 3A, 3B, 4A, 4B, 5A, 5B, 6A, 6B, 7A and 7B are cross-sectional views collectively showing schematically the manufacturing steps of a semiconductor device according to Example 1 of the present invention;

FIGS. 8A, 8B, 9A, 9B, 10A, 10B, 11A, 11B, 12A, 12B, 13A, 13B, 14A and 14B are cross-sectional views collectively showing schematically the manufacturing steps of a semiconductor device according to Example 2 of the present invention;

FIGS. 15A, 15B, 16A, 16B, 17A, 17B, 18A, 18B, 19A, 19B, 20A, and 20B are cross-sectional views collectively showing schematically the manufacturing steps of a semiconductor device according to Example 3 of the present invention;

FIGS. 21A, 21B, 22A, 22B, 23A, 23B, 24A, 24B, 25A, 25B, 26A, 26B, 27A and 27B are cross-sectional views collectively showing schematically the manufacturing steps of a semiconductor device according to Example 4 of the present invention;

FIGS. 28A, 28B, 29A, 29B, 30A, 30B, 31A, 31B, 32A, 32B, 33A and 33B are cross-sectional views collectively showing schematically the manufacturing steps of a semiconductor device according to Example 5 of the present invention;

FIGS. 34A, 34B, 35A, 35B, 36A, 36B, 37A, 37B, 38A, 38B, 39A and 39B are cross-sectional views collectively showing schematically the manufacturing steps of a semiconductor device according to Example 6 of the present invention; and

FIGS. 40A, 40B, 41A, 41B, 42A, 42B, 43A, 43B, 44A, 44B, 45A, 45B, 46A and 46B are cross-sectional views collectively showing schematically the manufacturing steps of a semiconductor device. according to Example 7 of the present invention.

### DETAILED DESCRIPTION OF THE INVENTION

The embodiments of the present invention will now be described.

The embodiments of the present invention are featured in that, after formation of a gate electrode (or a dummy gate) on a fin-type silicon layer, an impurity is introduced into the fin-type silicon layer with the gate electrode (or the dummy gate) used as a mask so as to form a first impurity region, followed by etching the gate electrode (or the dummy gate) so as to reduce the size of the gate electrode (or the dummy gate) and subsequently introducing an impurity into the fin-type silicon layer with the gate electrode (or the dummy gate) of reduced size used as a mask.

What should be noted is that, in the embodiments of the present invention, an impurity is introduced into the fin-type silicon layer both before and after the step of etching the gate electrode (or the dummy gate) for reducing the size of the gate electrode (or the dummy gate) so as to form the first and second impurity regions. The particular method of the embodiments of the present invention permits facilitating the formation of source/drain diffusion regions of a two-layer structure (LDD structure) in the fin-type silicon layer.

In the embodiments of the present invention, it is desirable for the fin-type silicon layer to have a height of about 0.1 to 0.2 μm and to have a thickness of about 0.01 to 0.1 μm. Also, it is desirable for the amount of reduction of the size achieved by the etching to be about 10 to 50 nm. Further, it is desirable for the dose of the impurity used for forming the first impurity region to be about 1×10¹³ to 1×10¹⁵/cm² and for the dose of the impurity used for forming the second impurity region to be about 1×10¹⁴ to 1×10¹⁶/cm².

In the manufacturing method of a semiconductor device according to a first aspect of the present invention, a gate material is deposited on the entire surface, followed by patterning the deposited gate material layer having a projecting portion corresponding to the fin-type silicon layer so as to form the gate electrode. It follows that the formed gate electrode has a projecting portion corresponding to the fin-type silicon layer.

Also, in the manufacturing method of a semiconductor device according to a second aspect of the present invention, a gate material is deposited on the entire surface, followed by planarizing the deposited gate material layer by, for example, chemical mechanical polishing (CMP) and subsequently patterning the planarized gate material layer so as to form the gate electrode. Such being the situation, the upper surface of the formed gate electrode is rendered flat. As a result, the focusing can be achieved easily in the patterning process, which is advantageous in carrying out fine gate processing.

In each of the first and second aspects of the present invention, it is possible to use a material containing as a main component polycrystalline silicon or amorphous silicon.

In the manufacturing method of a semiconductor device according to a third aspect of the present invention, the gate electrode has a two-layer structure. In the third aspect of the present invention, it is possible to use a material containing as a main component polycrystalline silicon or amorphous silicon as a material of the first gate or as a material of the second gate. Also, it is possible to use a material containing as a main component polycrystalline silicon or amorphous silicon as a material of the first gate and to use a metal or a metal silicide as a material of the second gate. The metal used for forming the second gate includes, for example, Ti, W, and Mo. On the other hand, the. metal silicide used for forming the second gate includes, for example, nickel silicide (NiSiₓ), titanium silicide (TiSiₓ), cobalt silicide (CoSiₓ), palladium silicide (PdSiₓ), molybdenum silicide (MoSiₓ), tantalum silicide (Ta Siₓ), niobium silicide (NbSiₓ), or platinum. silicide (PtSiₓ) in addition to tungsten silicide (WSiₓ).

Incidentally, it is desirable for the etching amount of the gate electrode to be smaller than the thickness of the mask material.

In the manufacturing method of a semiconductor device according to a fourth aspect of the present invention, a dummy gate material is deposited on the entire surface, followed by planarizing the deposited dummy gate material layer by, for example, CMP and, then, patterning the planarized dummy gate material layer so as to form a dummy gate. Then, first and second impurity regions are formed as in the first to third aspects of the present invention, followed by removing the dummy gate so as to form a gate groove. Further, a gate insulating film and a gate electrode are formed within the gate groove. It is possible to obtain a damascene metal gate in this fashion. In the fourth aspect of the present invention, it is possible to use a material containing as a main component polycrystalline silicon or amorphous silicon as a material of the dummy gate.

In the manufacturing method of a semiconductor device according to a fifth aspect of the present invention, formed is a dummy gate of a two-layer structure. In the fifth aspect of the present invention, it is possible to use a material containing polycrystalline silicon or amorphous silicon as a material of the first dummy gate and as a material of the second dummy gate. Alternatively, it is possible to use a material containing as a main component polycrystalline silicon or amorphous silicon for forming the first dummy gate and to use metal or metal silicide as a material for forming the second dummy gate. The specific examples of the metal and the metal silicide are equal to those exemplified above.

In the manufacturing method of a semiconductor device according to any of the fourth and fifth aspects of the present invention described above, it is desirable for the etching amount of the dummy gate to be not larger than the thickness of the mask material. Also, it is desirable for the impurity concentration in the first impurity region to be higher than that in the second impurity region. Further, it is possible for the silicon layer to be the silicon layer of the SOI substrate. Still further, it is possible to use silicon nitride as a masking material.

In the semiconductor device according to a Sixth aspect of the present invention, a first impurity region is formed in the fin-type silicon layer, and a second impurity region is formed on the outside of the first impurity region. It is possible for these first and second impurity regions to be formed without forming any side wall for the gate electrode or the dummy gate. In the sixth aspect of the present invention, it is desirable for the width of the first impurity region to be smaller than the thickness of the mask material.

In the semiconductor device according to a seventh aspect of the present invention, the mask material positioned on the fin-type silicon layer is removed. As a result, it is possible to form a channel on the fin-type silicon layer so as to make it possible to increase the driving force of the entire transistor. In the seventh aspect of the present invention, it is desirable for the impurity concentration in the second impurity region to be higher than that in the first impurity region. Also, it is possible to use a metal or a metal silicide for forming the gate electrode. Alternatively, it is also possible to use a material containing polycrystalline silicon or amorphous silicon for forming the gate electrode.

In the semiconductor device according to an eighth aspect of the present invention, a first gate and a second gate are formed on both sides of the fin-type silicon layer. In other words, the eighth aspect of the present invention provides a fin-type field-effect semiconductor device of a double gate structure.

In the semiconductor device according to a ninth aspect of the present invention, a first gate and a second gate are formed on both sides of the fin-type silicon layer and, at the same time, a third gate is formed on the upper surface of the fin-type silicon layer. In the ninth aspect of the present invention, it is possible to use a material containing as a main component polycrystalline silicon or amorphous silicon for forming each of the first, second and third gate electrodes. Also, it is possible to make the width of the third gate electrode larger than the width of each of the first and second gate electrodes. In this case, it is possible to use a material containing as a main component polycrystalline silicon or an aqueous solution for forming each of the first and second gate electrodes and to use a metal or a metal silicide for forming the third gate electrode.

In each of the sixth to ninth aspects of the present invention, it is possible to make the impurity concentration in the first impurity region higher than that in the second impurity region.

Various Examples of the present invention will now be described with reference to the accompanying drawings.

### EXAMPLE 1

Example 1 is directed to a case where the gate electrode comprises polycrystalline silicon, and the gate is not planarized.

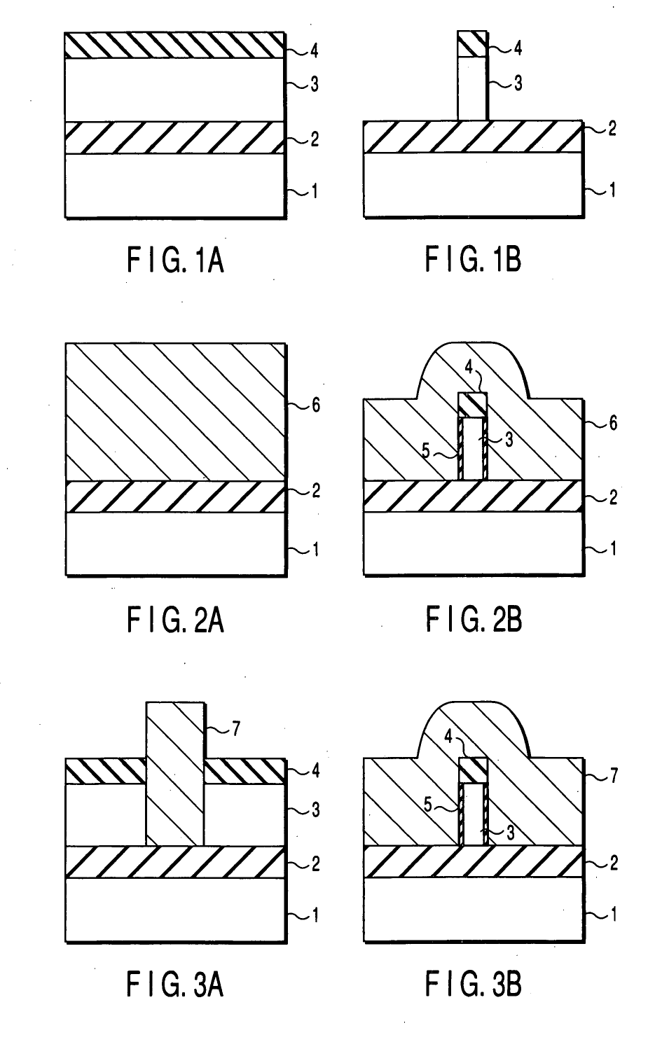

In the first step, a silicon nitride film used as a mask is deposited on the entire surface of an SOI substrate with a buffer oxide film interposed therebetween. Then, the silicon nitride film, the buffer oxide film and the SOI active layer are etched successively by anisotropic etching such as RIE with a resist pattern used as a mask so as to obtain a structure that an insulating layer 2 is formed on a silicon substrate 1 and an Si-fin layer 3 is formed on the insulating layer 2, as shown in FIGS. 1A and 1B. As shown in the drawings, the Si-fin layer 3 is covered with a silicon nitride film 4 used as a mask.

In the next step, a gate insulating film 5 is formed on the entire surface, followed by depositing a polycrystalline silicon film or an amorphous silicon film 6 as a material for forming the gate electrode, as shown in FIGS. 2A and 2B. Then, the gate electrode material layer is processed by patterning and anisotropic etching so as to form a gate electrode 7 as shown in FIGS. 3A and 3B. In this case, the width of the gate electrode 7 denotes the width of the mask used for forming source and drain diffusion regions and, thus, differs from the final gate width.

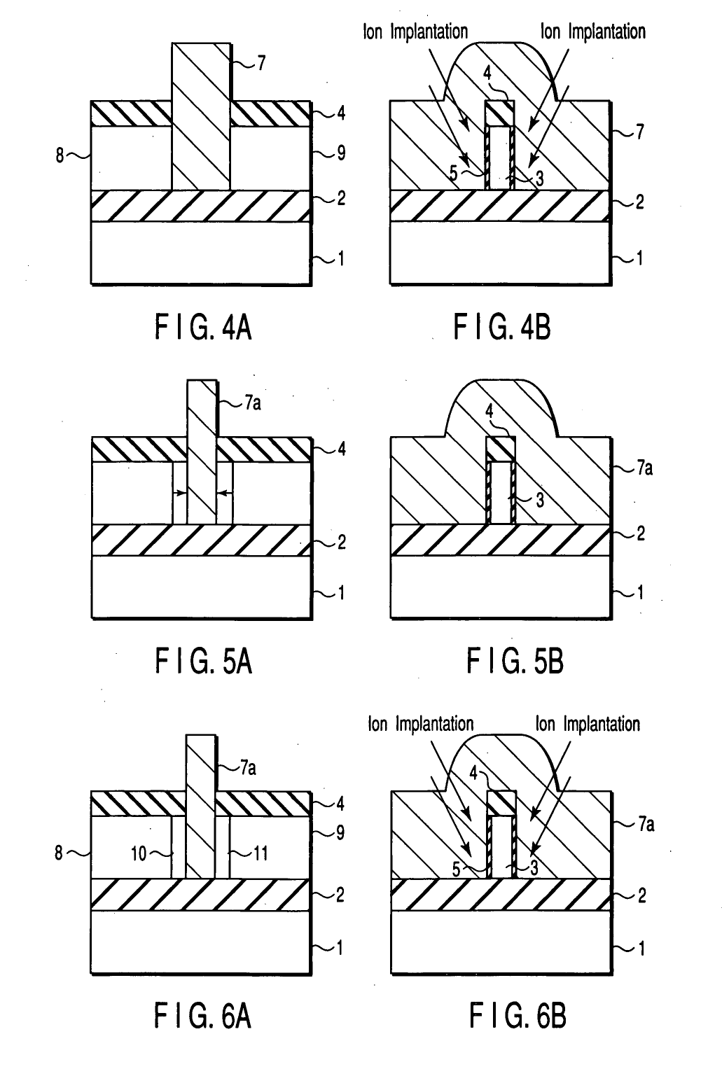

After formation of the gate electrode 7, an impurity is introduced into the Si-fin layer 3 by means of ion implantation with the gate electrode 7 used as a mask so as to form a source diffusion region 8 and a drain diffusion region 9, as shown in FIGS. 4A and 4B. After formation of the source diffusion region 8 and the drain diffusion region 9, the size of the gate electrode 7 is reduced by the etching. utilizing the isotropic etching technology such as chemical dry etching (CDE) so as to obtain a gate electrode 7a of the final gate size, as shown in FIGS. 5A and 5B.

In the next step, an impurity is introduced into the Si-fin layer 3 by means of ion implantation with the gate electrode 7a used as a mask so as to form extended regions 10 and 11, as shown in FIGS. 6A and 6B, followed by activating the impurity by means of an annealing treatment.

Further, a wiring process is applied by the procedure equal to that in the ordinary method of manufacturing transistor and, then, the silicon nitride film mask 4 is removed, followed by forming a silicon nitride liner on the entire surface. After formation of the silicon nitride liner, an interlayer film is deposited on the entire surface, followed by formation of a contact hole and formation of a contact so as to finish the wiring process, thereby completing the manufacture of the transistor.

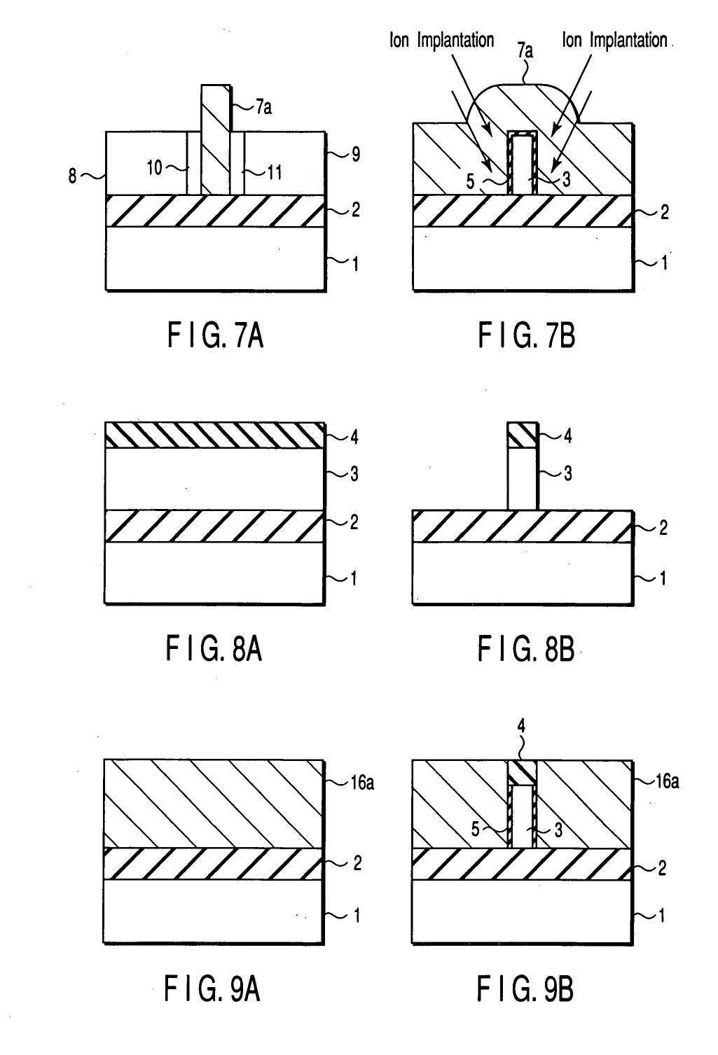

In Example 1 described above, the gate electrode was formed with the silicon nitride film mask 4 left unremoved. However, it is possible to remove the silicon nitride film mask 4 before formation of the gate insulating film 5. FIGS. 7A and 7B collectively show the construction of the transistor thus obtained. In the transistor of the particular construction, it is possible to form a channel portion in also an upper portion of the silicon active layer 3 so as to obtain the merit that it is possible to increase the driving force of the entire transistor.

### EXAMPLE 2

Example 2 is directed to an example in which is formed a silicon gate electrode of a two-layer structure.

As shown in FIGS. 8A and 8B, the insulating layer 2 is formed on the Si substrate 1, and the Si-fin layer 3 is formed on the insulating layer 2 as in Example 1 described above. As shown in the drawings, the Si-fin layer 3 is covered with the silicon nitride film 4 used as a mask.

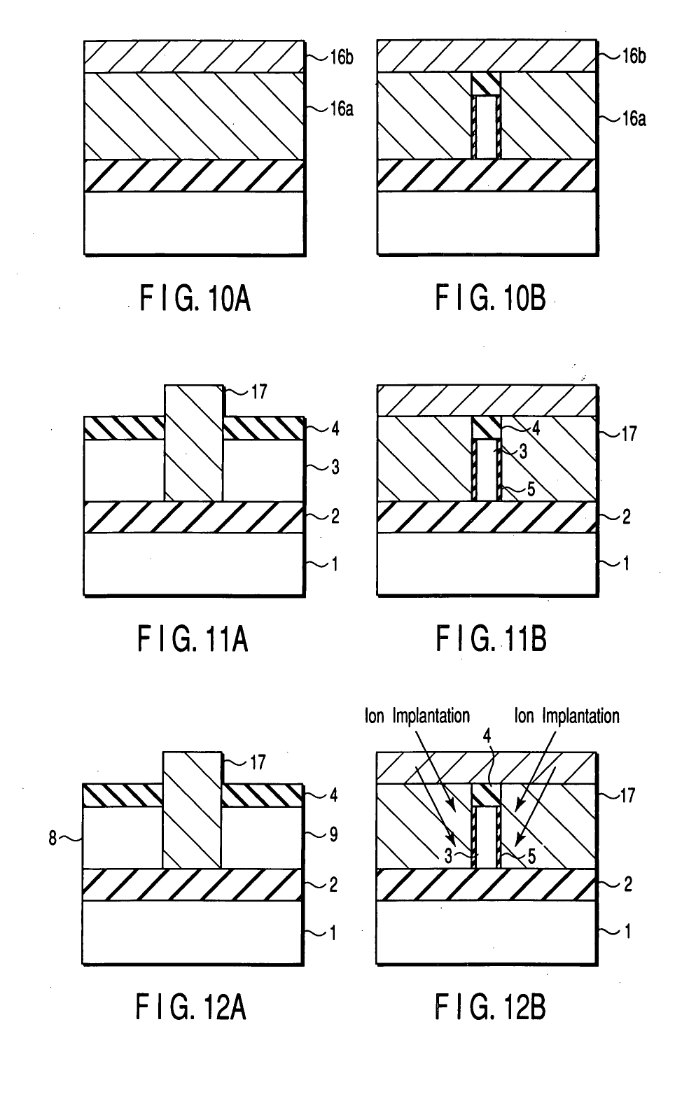

After formation of the gate insulating film 5 on the surface of the Si-fin layer 3, a polycrystalline silicon or amorphous silicon film 16a is formed as a material used for forming the first gate electrode, as shown in FIGS. 9A and 9B, followed by planarizing the polycrystalline silicon or amorphous silicon film 16a by, for example, CMP until the surface of the silicon nitride film 4 is exposed to the outside. After planarization of the polycrystalline silicon or amorphous silicon film 16a, a polycrystalline silicon or amorphous silicon film 16b is formed as a material used for forming a second gate electrode, as shown in FIGS. 10A and 10B.

In the next step, the polycrystalline silicon or amorphous silicon films 16a and 16b are processed simultaneously by the patterning and the anisotropic etching so as to form a gate electrode 17 as shown in FIGS. 11A and 11B. In this case, the width of the gate electrode 17 denotes the width of the mask used for forming source and drain regions and, thus, differs from the final gate width.

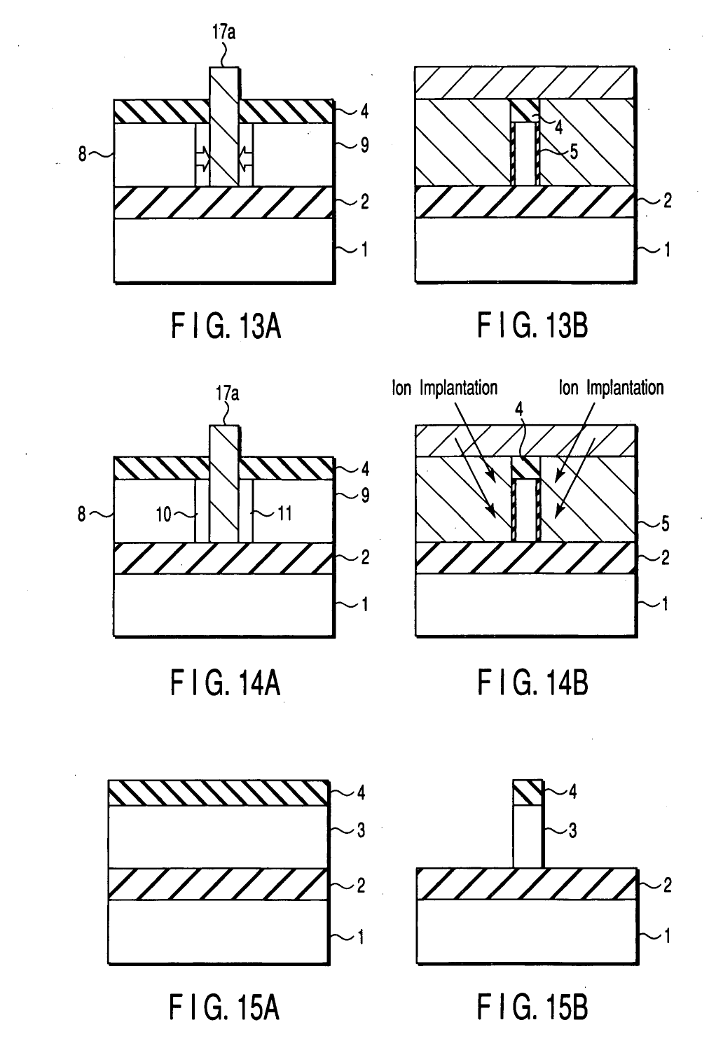

After formation of the gate electrode 17, an impurity is introduced into the Si-fin layer 3 by means. of ion implantation with the gate electrode 7 used as a mask so as to form a source diffusion region 8 and a drain diffusion region 9 as shown in FIGS. 12A and 12B. After formation of the source diffusion region 8 and the drain diffusion region 9, the size of the gate electrode 7 is reduced by the etching utilizing isotropic etching technology such as chemical dry etching (CDE) so as to obtain a gate electrode 17a of the final gate size, as shown in FIGS. 13A and 13B.

In the next step, an impurity is introduced into the Si-fin layer 3 by means of ion implantation with the gate electrode 17a used as a mask, as shown in FIGS. 14A and 14B, so as to form extended regions 10 and 11, followed by activating the impurity by an annealing process.

Further, a wiring process is applied by the. procedure equal to that in the ordinary method of manufacturing transistor and, then, the silicon nitride film mask 4 is removed, followed by forming a silicon nitride liner on the entire surface. After formation of the silicon nitride liner, an interlayer film is deposited on the entire surface, followed by formation of a contact hole and formation of a contact so as to finish the wiring process, thereby completing the manufacture of the transistor.

In Example 2 described above, the upper surface of the gate electrode is rendered flat in the patterning stage of the gate electrode, with the result that the focusing for the patterning can be facilitated. This is advantageous in carrying out a fine processing.

### EXAMPLE 3

Example 3 is directed to an example of forming a polycrystalline silicon gate electrode having a planarized surface.

In the first step, a silicon nitride film used as a mask is deposited on the entire surface of an SOI substrate with a buffer oxide film interposed therebetween. Then, the silicon nitride film, the buffer oxide film and the SOI active layer are etched successively by anisotropic etching such as RIE with a resist pattern used as a mask so as to obtain a structure that an insulating layer 2 is formed on a silicon substrate 1 and an Si-fin layer 3 is formed on the insulating layer 2, as shown in FIGS. 15A and 15B. As shown in the drawings, the Si-fin layer 3 is covered with a silicon nitride film 4 used as a mask.

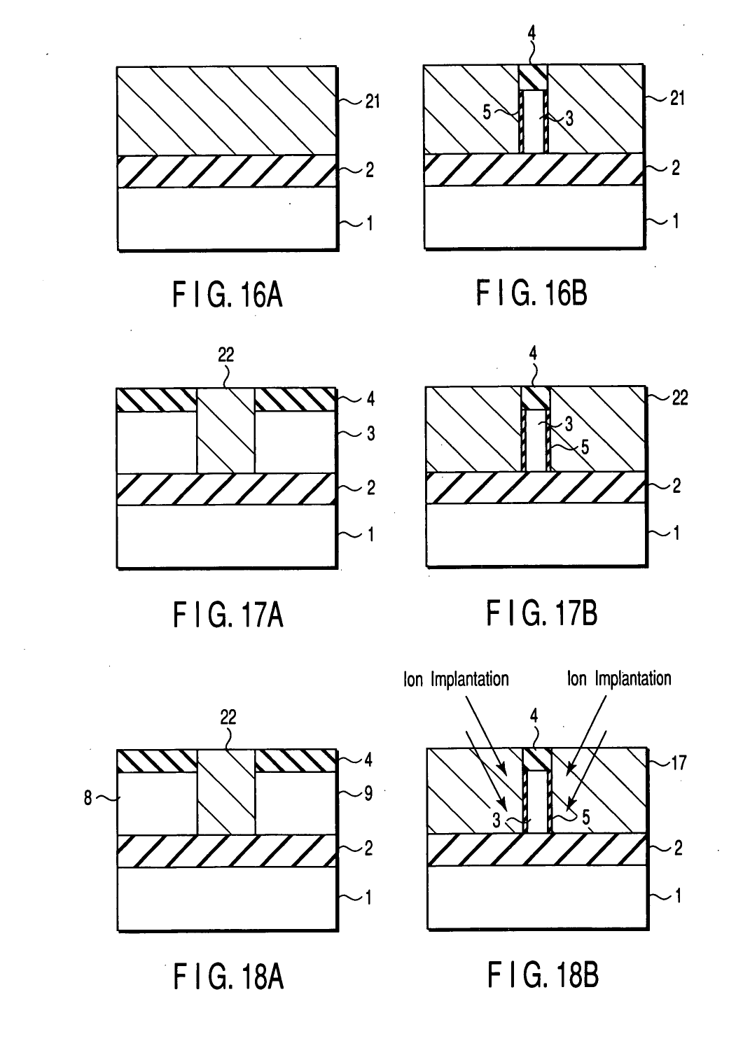

In the next step, a gate insulating film 5 is formed on the entire surface, followed by depositing a polycrystalline silicon film or an amorphous silicon film 21 as a material for forming the gate electrode, as shown in FIGS. 16A and 16B. Then, a polycrystalline silicon or amorphous silicon film 21 is deposited to form a layer used for forming a gate electrode, followed by planarizing by, for example, CMP the polycrystalline silicon or amorphous silicon film 21 until the surface of the silicon nitride film 4 is exposed to the outside.

In the next step, a resist (not shown) having a prescribed pattern is formed on the polycrystalline silicon or amorphous silicon film 21 for processing the polycrystalline silicon or amorphous silicon film 21 by anisotropic etching so as to form a gate electrode 22 as shown in FIGS. 17A and 17B. In this stage, the width of the gate electrode 22 denotes the width of the mask used for forming a source diffusion region and a drain diffusion region and is larger than the final gate size.

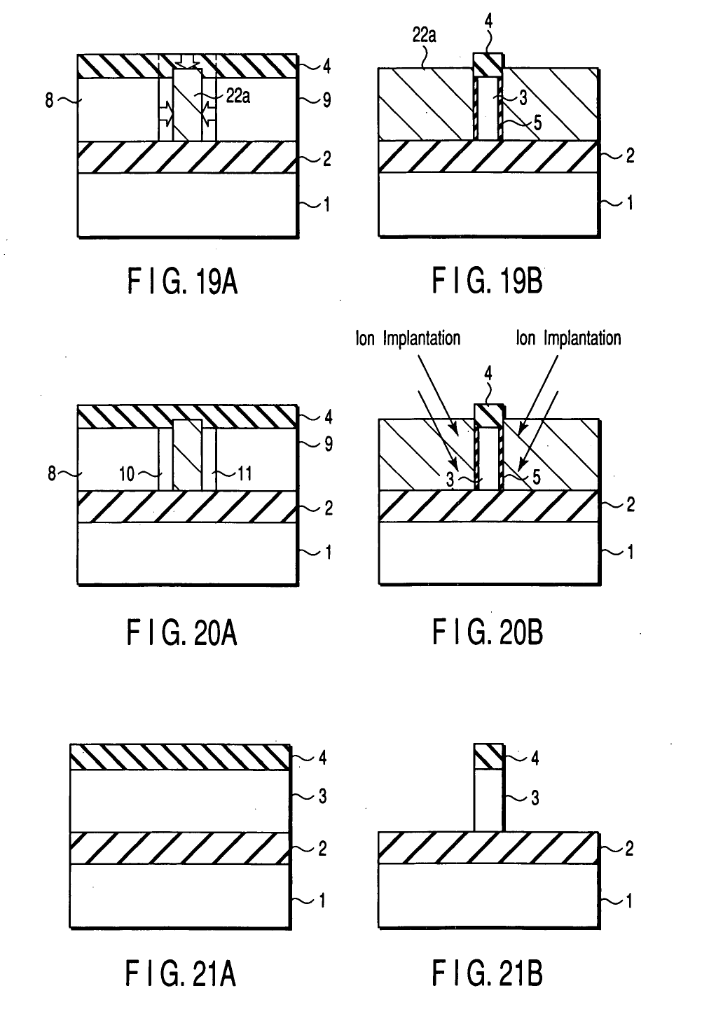

In the next step, an impurity is introduced into the Si-fin layer 3 by means of ion implantation with the gate electrode 22 used as a mask so as to form a source diffusion region 8 and a drain diffusion region 9, as shown in FIGS. 18A and 18B. Then, the size of the gate electrode 22 is reduced by the etching utilizing an isotropic etching technology such as chemical dry etching (CDE) so as to obtain a gate electrode 22 having a final gate size, as shown in FIGS. 19A and 19B.

Further, an impurity is introduced into the Si-fin layer 3 by means of ion implantation with the gate electrode 22a used as a mask so as to form extended regions 10 and 11, as shown in FIGS. 20A and 20B, followed by activating the impurity by means of an annealing treatment.

Still further, a wiring process is applied by the procedure equal to that in the ordinary method of manufacturing transistor and, then, the silicon nitride film mask 4 is removed, followed by forming a silicon nitride liner on the entire surface. After formation of the silicon nitride liner, an interlayer film is deposited on the entire surface, followed by formation of a contact hole and formation of a contact so as to finish the wiring process, thereby completing the manufacture of the transistor.

According to Example 3, the upper surface of the gate electrode is made flat in the patterning stage of the gate electrode. As a result, the focusing in the patterning stage can be facilitated, which is advantageous in carrying out a fine gate processing.

### EXAMPLE 4

Example 4 is directed to a case where a tungsten silicide (WSi) film is laminated on the silicon gate electrode.

As shown in FIGS. 21A and 21B, an insulating film 2 is formed on a silicon substrate 1, and an Si-fin layer 3 is formed on the insulating film 2 as in Example 1. Also, the Si-fin layer 3 is covered with a silicon nitride film 4 used as a mask.

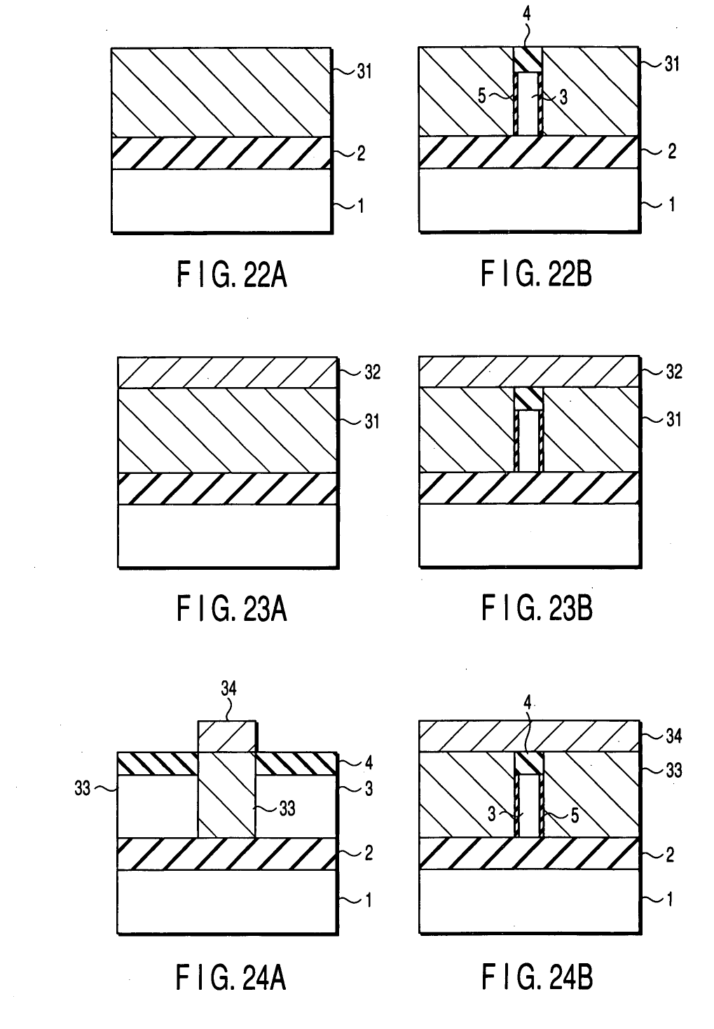

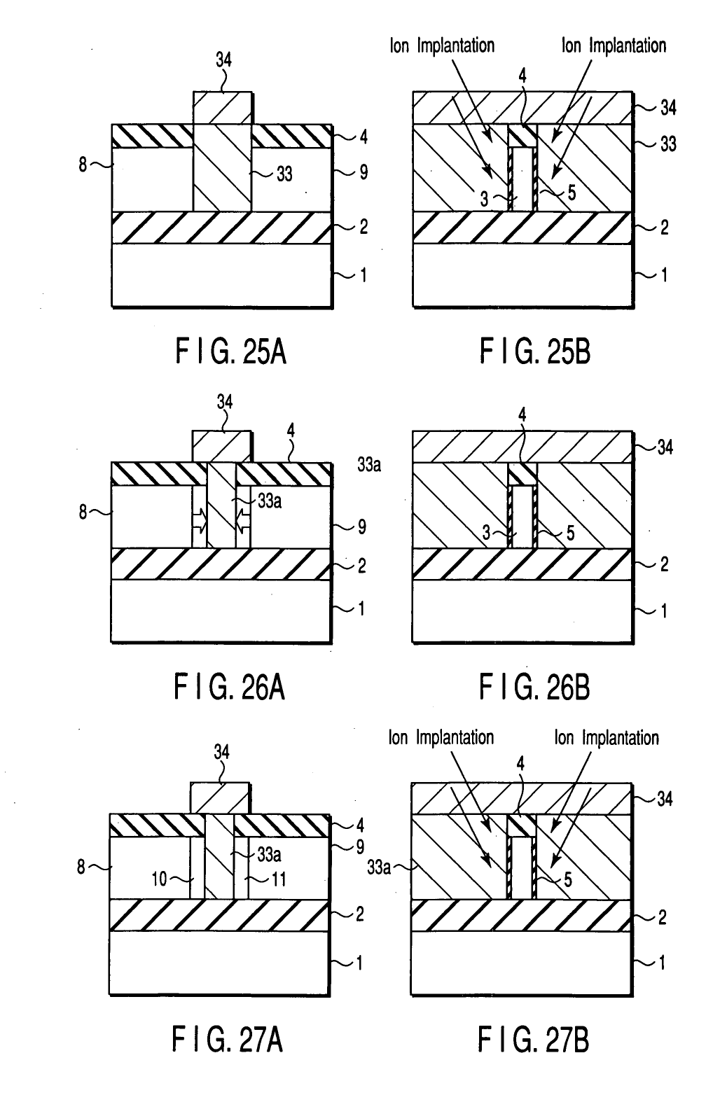

After formation of the gate insulating film 5 on the surface of the Si-fin layer 3, a polycrystalline silicon or amorphous silicon film 31 is deposited to form a layer used for forming a first gate electrode, followed by planarizing the polycrystalline silicon or amorphous silicon film 31 by, for example, CMP until the silicon nitride film 4 is exposed to the outside, as shown in FIGS. 22A and 22B. In the next step, a tungsten silicide (WSi) film 32 used for forming a second gate electrode is formed as shown in FIGS. 23A and 23B.

After formation of the tungsten silicide (WSi) film 32, the tungsten silicide (WSi) film 32 and the polycrystalline silicon or amorphous silicon film 31 are processed simultaneously by patterning and anisotropic etching so as to form gate electrodes 33 and 34, as shown in FIGS. 24A and 24B. The widths of the gate electrodes 33 and 34 in this stage denote the width of the mask used for forming the source and drain regions and, thus, differ from the final gate widths.

After formation of the gate electrodes 33 and 34, an impurity is introduced into the Si-fin layer 3 by means of ion implantation with the gate electrodes 33. and 34 used as a mask so as to form a source diffusion region 8 and a drain diffusion region 9. Then, an etching is performed by means of an isotropic etching technology such as chemical dry etching (CDE) so as to reduce the size of the first gate electrode 33, thereby obtaining gate electrodes 33a and 34 having the final gate size, as shown in FIGS. 26A and 26B.

In the next step, an impurity is introduced into the Si-fin layer 3 by means of ion implantation with the gate electrodes 33a and 34 used as a mask so as to form extended regions 10 and 11, as shown in FIGS. 27A and 27B, followed by activating the impurity by means of an annealing treatment.

Further, a wiring process is applied by the procedure equal to that in the ordinary method of manufacturing transistor and, then, the silicon nitride film mask 4 is removed, followed by forming a silicon nitride liner on the entire surface. After formation of the silicon nitride liner, an interlayer film is deposited on the entire surface, followed by formation of a contact hole and formation of a contact so as to finish the wiring process, thereby completing the manufacture of the transistor.

According to Example 4, the gate electrode comprises a first gate electrode formed of a polycrystalline silicon or amorphous silicon and a second gate electrode formed of tungsten silicide (WSi). As a result, it is possible to lower the resistance of the gate electrode. It follows that the manufactured transistor is adapted for a high speed operation.

### EXAMPLE 5

Example 5 is directed to a case where a fin-type field-effect transistor (FET) is manufactured by using a damascene metal gate.

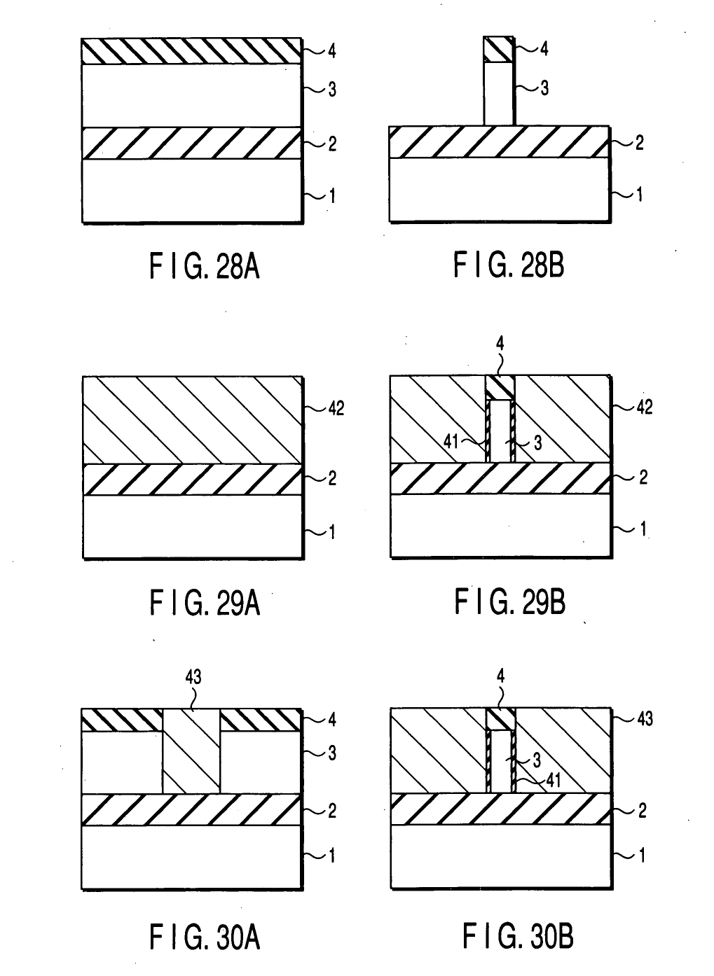

In the first step, a silicon nitride film that is used later as a mask is deposited on the entire surface of an SOI substrate with a buffer oxide film interposed therebetween. Then, the silicon nitride film, the buffer oxide film and the SOI active layer are successively etched by anisotropic etching such as RIE with a resist pattern used as a mask so as to obtain a structure that an insulating film 2 is formed on an Si substrate 1 and an Si-fin layer 3 is formed on the insulating film 2 as shown in FIGS. 28A and 28B. It should be noted that the Si-fin layer 3 is covered with the silicon nitride film 4 used as the mask.

In the next step, after formation of a buffer film 41 by, for example, oxidation of the side surface of the exposed Si-fin layer 3, a polycrystalline silicon or amorphous silicon film (dummy silicon film) 42 is formed on the entire surface, followed by planarizing the dummy silicon film 42 by, for example, CMP until the silicon nitride film 4 is exposed to the outside, as shown in FIGS. 29A and 29B.

After planarization of the dummy silicon film 42, a resist (not shown) of a prescribed pattern is formed for processing the dummy silicon film 42 by anisotropic etching so as to form a dummy gate 43 as shown in FIGS. 30A and 30B. It should be noted that the width of the dummy gate 43 denotes the width of a mask used for forming source and drain diffusion regions and is larger than the final gate size.

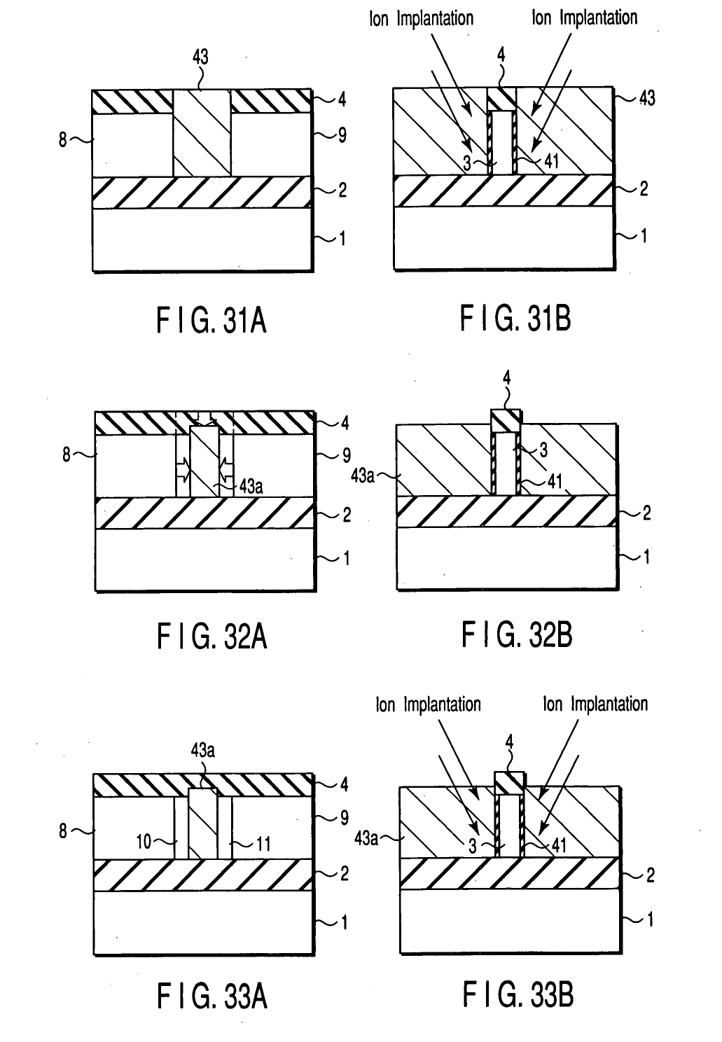

In the next step, an impurity is introduced into the Si-fin layer 3 by means of ion implantation with the dummy gate 43 used as a mask so as to form a source diffusion region 8 and a drain diffusion region 9, as shown in FIGS. 31A and 31B. Then, an etching is performed by means of an isotropic etching technology such as chemical dry etching (CDE) so as to reduce the size of the dummy gate 43, thereby obtaining a dummy gate 43a having the final gate size, as shown in FIGS. 32A and 32B.

In the next step, an impurity is introduced into the Si-fin layer 3 by means of ion implantation with the dummy gate 43 used as a mask so as to form extended regions 10 and 11, as shown in FIGS. 33A and 33B, followed by activating the impurity by means of an annealing treatment.

In this case, it is necessary for that portion of the silicon nitride film 4 which crosses the dummy gate 43a on the Si-fin layer 3 to have a thickness corresponding to an amount not smaller than the amount required for isotropically etching the dummy gate 43a. It should be noted in this connection that, since the dummy gate 43a is etched from the upper surface, an impurity is introduced by the ion implantation into that portion of the Si-fin layer 3 into which the impurity should not be introduced, if the silicon nitride film 4 having a thickness not smaller than the etching amount is not present. It follows that the diffusion regions are rendered contiguous so as to make the transistor inoperative.

In the next step, the silicon nitride film 4 is removed by the treatment with, for example, a hot phosphoric acid, followed by depositing a silicon nitride liner on the entire surface and subsequently forming a silicon oxide film as an interlayer film. After formation of the silicon oxide film, a planarizing treatment such as CMP is applied so as to expose the silicon nitride film on the upper surface of the dummy gate 43a to the outside. Then, the nitride liner is removed by an etching treatment so as to expose the dummy gate 43a to the outside. Further, the dummy gate 43a is removed by, for example, CDE so as to complete formation of a gate groove.

After formation of the gate groove, ion implantation and an activating annealing treatment are applied as required to the channel portion so as to adjust the impurity concentration in the channel portion, followed by removing the buffer oxide film and forming a gate insulating film in the gate groove portion. Further, a gate electrode material of, for example, titanium nitride is deposited on the entire surface. The gate electrode can be processed by using a pattern slightly larger than the gate pattern so as to form a so-called T-shaped gate. It is also possible to bury the gate electrode in the gate groove by means of CMP.

Where the gate electrode is buried in the groove, the gate electrode is divided by the Si-fin layer 3 into two regions positioned on both sides of the Si-fin layer 3. Such being the situation, it is necessary to form contacts leading to the gate electrode in the gate electrode regions positioned on both sides of the Si-fin layer 3. It is also possible to form a new conductive material layer after the planarizing process, followed by patterning the new conductive material layer such that required portions alone are selectively left unremoved so as to form the gate electrodes.

After formation of the gate electrode, an ordinary. method of forming a transistor is employed for completing the formation of the transistor. To be more specific, an interlayer film is deposited on the entire surface, followed by forming a contact hole and subsequently burying a metal in the contact hole so as to form a contact. Then, a metal layer such as an aluminum layer is formed on the entire surface, followed by patterning the metal layer in a desired shape so as to form a wiring, thereby completing the formation of the transistor.

### EXAMPLE 6

Example 6 is directed to a case where dummy gates are formed of a plurality of layers.

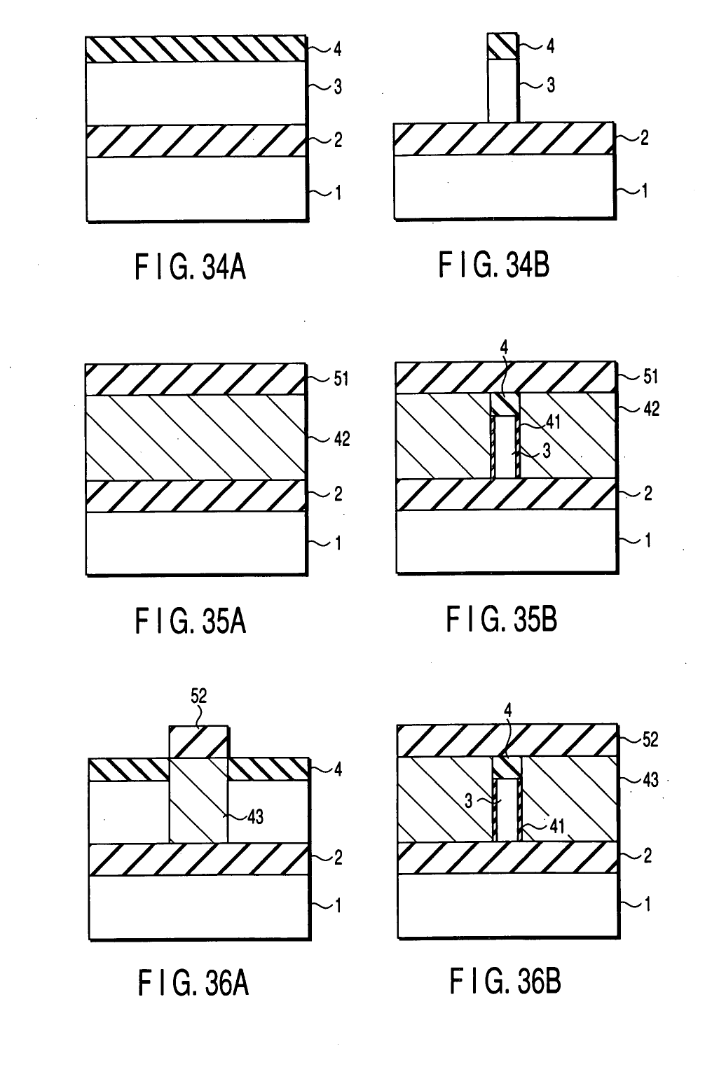

In the first step, a silicon nitride film that is used later as a mask is deposited on the entire surface of an SOI substrate with a buffer oxide film interposed therebetween. Then, the silicon nitride film, the buffer oxide film and the SOI active layer are successively etched by anisotropic etching such as RIE with a resist pattern used as a mask so as to obtain a structure that an insulating film 2 is formed on an Si substrate 1 and an Si-fin layer 3 is formed on the insulating film 2 as shown in FIGS. 34A and 34B. It should be noted that the Si-fin layer 3 is covered with. the silicon nitride film 4 used as the mask.

In the next step, the exposed side surfaces of the Si-fin layer 3 are oxidized so as to form a buffer film 41 as shown in FIGS. 35A and 35B, followed by forming a polycrystalline silicon or amorphous silicon film (dummy silicon film) 42 on the entire surface and subsequently planarizing the dummy silicon film 42 by, for example, CMP until the silicon nitride film 4 is exposed to the outside. Then, a silicon oxide film 51 is deposited on the entire surface.

Further, the silicon oxide film 51 and the dummy silicon film 42 are subjected to anisotropic etching with a resist (not shown) of a dummy gate pattern used as a mask so as to form two layers of dummy gates 43 and 52 consisting of a silicon oxide film and a silicon film, respectively, as shown in FIGS. 36A and 36B. The width of the gate pattern in this stage denotes the width of a mask used for forming source drain diffusion regions, and is larger than the final gate size.

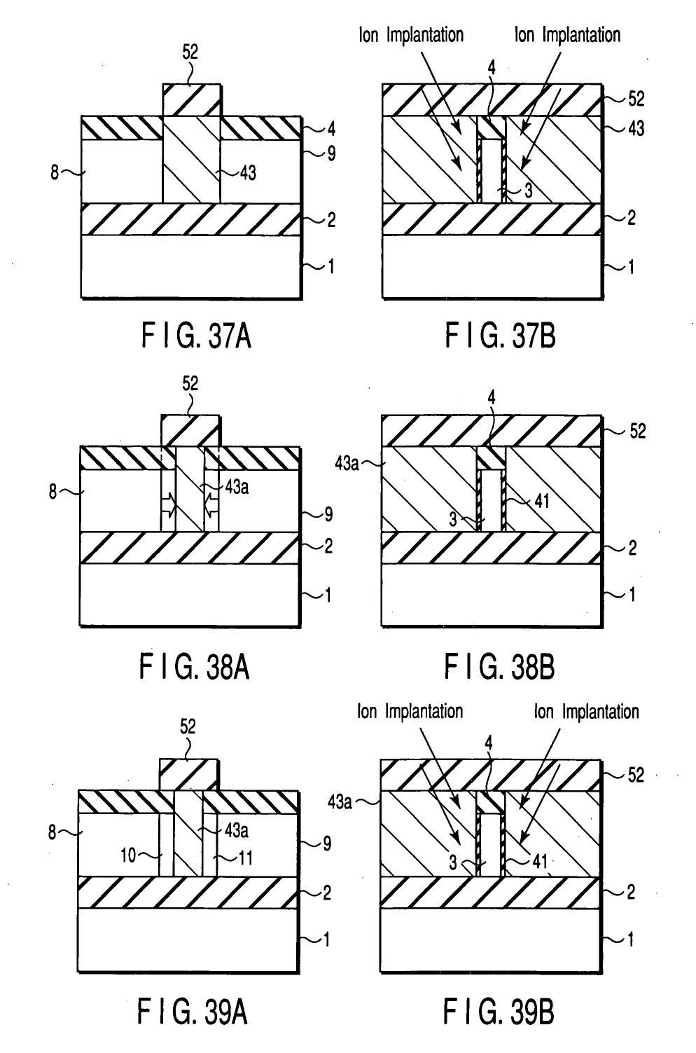

In the next step, an impurity is introduced into the Si-fin layer 3 by means of ion implantation with the dummy gates 43, 52 used as a mask so as to form a source diffusion region 8 and a drain diffusion region 9, as shown in FIGS. 37A and 37B. Then, the size of the dummy gate 43 is reduced by an etching utilizing an isotropic etching technology such as chemical dry etching (CDE) as shown in FIGS. 38A and 38B so as to obtain a dummy gate 43a of the final gate size.

After formation of the dummy gate 43a, an impurity is introduced into the Si-fin layer 3 by means of ion implantation with the dummy gates 43a, 52 used as a mask, as shown in FIGS. 39A and 39B so as to form extended regions 10 and 11, followed by activating the impurity by an annealing treatment.

In the next step, a silicon nitride liner is deposited on the entire surface, followed by forming a silicon oxide film as an interlayer film. Then, the interlayer silicon oxide film is planarized by, for example, CMP so as to expose the upper surfaces of the dummy gates 43a, 52 to the outside. In this stage, the silicon nitride liner and the interlayer silicon oxide film positioned on the dummy gates 43a, 52 are removed simultaneously. Further, the dummy gates 43a, 52 are removed by, for example, CDE so as to form a gate groove.

After formation of the gate groove, ion implantation and an activating annealing treatment are applied as required to the channel portion so as to adjust the impurity concentration in the channel portion, followed by removing the buffer oxide film and forming a gate insulating film on the inner surface of the gate groove. Further, a gate electrode material of, for example, titanium nitride is deposited on the entire surface. The gate electrode can be processed by using a pattern slightly larger than the gate pattern so as to form a so-called T-shaped gate. It is also possible to bury the gate electrode in the gate groove by means of CMP.

Where the gate electrode is buried in the groove, the gate electrode is divided by the Si-fin layer 3 into two regions positioned on both sides of the Si-fin layer 3. Such being the situation, it is necessary to form contacts leading to the gate electrode in the gate electrode regions positioned on both sides of the Si-fin layer 3. It is also possible to form a new conductive material layer after the planarizing process, followed by patterning the new conductive material layer such that required portions alone are selectively left unremoved so as to form the gate electrodes.

After formation of the gate electrode, an ordinary method of forming a transistor is employed for completing the formation of the transistor. To be more specific, an interlayer film is deposited on the entire surface, followed by forming a contact hole and subsequently burying a metal in the contact hole so as to form a contact. Then, a metal layer such as an aluminum layer is formed on the entire surface, followed by processing the metal layer in a desired pattern so as to form a wiring, thereby completing the formation of the transistor.

Since it is possible to permit the silicon nitride film mask to be left unremoved on the Si-fin layer in Example 6, the side surface alone of the Si-fin layer is utilized as a transistor. In other words, since the upper portion of the Si-fin layer is not utilized as a channel, it is possible to obtain a merit that the design of the transistor can be facilitated.

### EXAMPLE 7

Example 7 is directed to a case where dummy gates are formed of a plurality of layers.

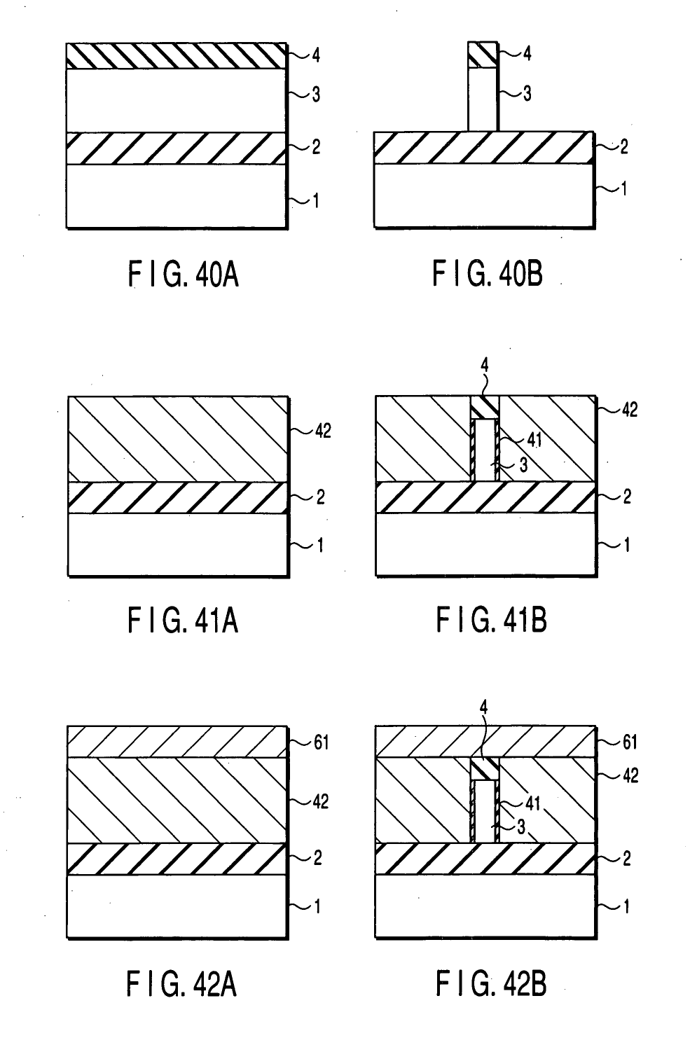

In the first step, a silicon nitride film that is used later as a mask is deposited on the entire surface of an SOI substrate with a buffer oxide film interposed therebetween. Then, the silicon nitride film, the buffer oxide film and the SOI active layer are successively etched by anisotropic etching such as RIE with a resist pattern used as a mask so as to obtain a structure that an insulating film 2 is formed on an Si substrate 1 and an Si-fin layer 3 is formed on the insulating film 2 as shown in FIGS. 40A and 40B. It should be noted that the Si-fin layer 3 is covered with the silicon nitride film 4 used as the mask.

In the next step, the exposed side surfaces of the Si-fin layer 3 are oxidized so as to form a buffer film 41 as shown in FIGS. 41A and 41B, followed by forming a polycrystalline silicon or amorphous silicon film (dummy silicon film) 42 on the entire surface and subsequently planarizing the dummy silicon film 42 by, for example, CMP until the silicon nitride film 4 is exposed to the outside.

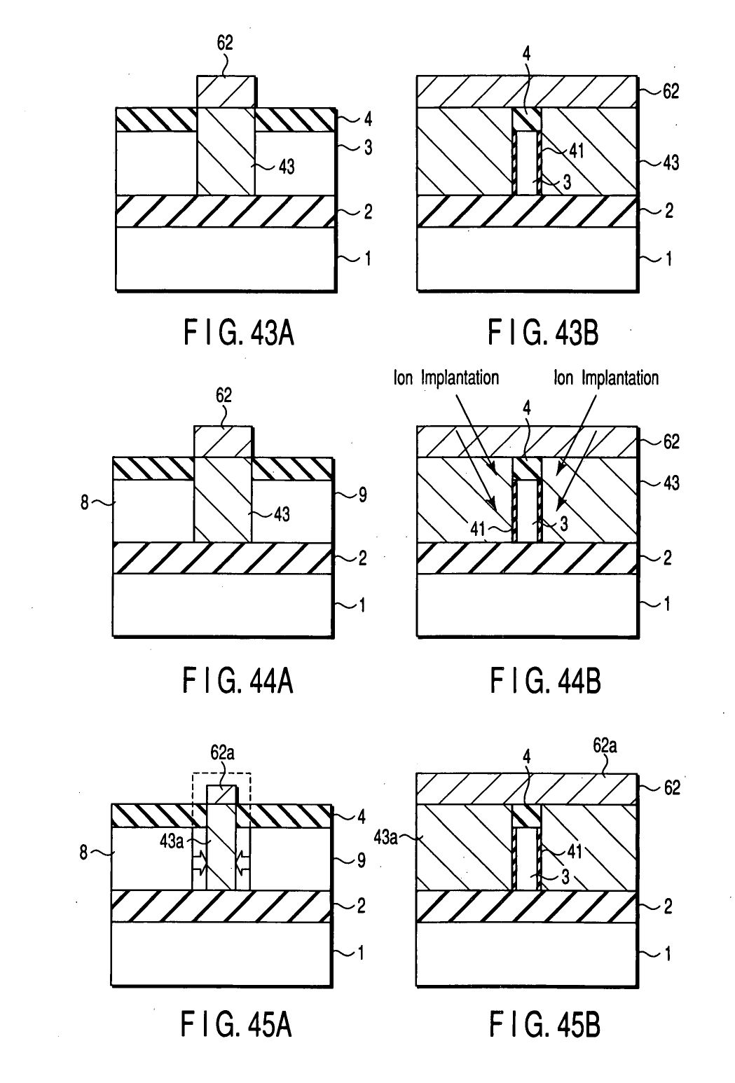

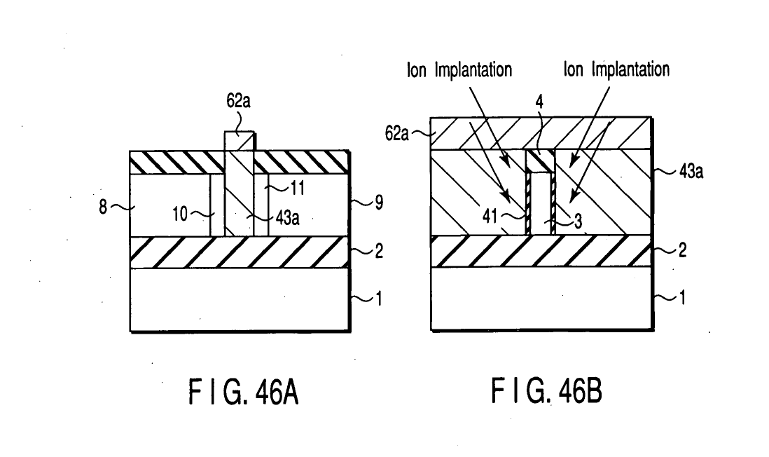

In the next step, a second dummy silicon film 61 is deposited on the entire surface, as shown in FIGS. 42A and 42B. Then, the dummy silicon film 42 and 61 are subjected to anisotropic etching with a resist (not shown) of a dummy gate pattern used as a mask so as to form dummy gates 43 and 62, as shown in FIGS. 43A and 43B. The width of the gate pattern in this stage denotes the width of a mask used for forming source drain diffusion regions, and is larger than the final gate size.

In the next step, an impurity is introduced into the Si-fin layer 3 by means of ion implantation with the dummy gates 43, 62 used as a mask so as to form a source diffusion region 8 and a drain diffusion region 9, as shown in FIGS. 44A and 44B. Then, the sizes of the dummy gates 43 and 62 is reduced by an etching utilizing an isotropic etching technology such as chemical dry etching (CDE) as shown in FIGS. 45A and 45B so as to obtain dummy gates 43a and 62a of the final gate size.

After formation of the dummy gates 43a and 62a, an impurity is introduced into the Si-fin layer 3 by means of ion implantation with the dummy gates 43a, 62a used as a mask, as shown in FIGS. 44A and 44B so as to form extended regions 10 and 11, followed by activating the impurity by an annealing treatment.

In the next step, a silicon nitride liner is deposited on the entire surface, followed by forming a silicon oxide film as an interlayer film. Then, the interlayer silicon oxide film is planarized by, for example, CMP so as to expose the upper surfaces of the dummy gates 43a, 62a to the outside. In this stage, the silicon nitride liner and the interlayer silicon oxide film positioned on the dummy gates 43a, 62a are removed simultaneously. Further, the dummy gates 43a, 62a are removed by, for example, CDE so as 'to form a gate groove.

After formation of the gate groove, ion implantation and an activating annealing treatment are applied as required to the channel portion so as to adjust the impurity concentration in the channel portion, followed by removing the buffer oxide film and forming a gate insulating film on the inner surface of the gate groove. Further, a gate electrode material of, for example, titanium nitride is deposited on the entire surface. The gate electrode can be processed by using a pattern slightly larger than the gate pattern so as to form a so-called T-shaped gate. It is also possible to bury the gate electrode in the gate groove by means of CMP.

Where the gate electrode is buried in the groove, the gate electrode is divided by the Si-fin layer 3 into two regions positioned on both sides of the Si-fin layer 3. Such being the situation, it is necessary to form contacts leading to the gate electrode in the gate electrode regions positioned on both sides of the Si-fin layer 3. It is also possible to form a new conductive material layer after the planarizing process, followed by patterning the new conductive material layer such that required portions alone are selectively left unremoved so as to form the gate electrodes.

Incidentally, if the thickness of the second dummy silicon layer is made larger than at least the etching amount (size reduction) after the source/drain ion implantation, the dummy gate is not divided into two regions even after the planarizing process, with the result that it is not absolutely necessary to form contacts on both sides of the gate.

After formation of the gate electrode, an ordinary method of forming a transistor is employed for completing the formation of the transistor. To be more specific, an interlayer film is deposited on the entire surface, followed by forming a contact hole and subsequently burying a metal in the contact hole so as to form a contact. Then, a metal layer such as an aluminum layer is formed on the entire surface, followed by processing the metal layer in a desired pattern so as to form a wiring, thereby completing the formation of the transistor.

The present invention is not limited to the Examples described above. It is possible to modify the present invention in various fashions within the technical scope of the present invention.

To be more specific, an SOI substrate was used in each of the Examples described above. However, it is also possible to use an ordinary silicon substrate in the present invention. In the case of using the ordinary silicon substrate, it is necessary to process the Si-fin layer by etching the silicon substrate in a prescribed depth, which corresponds to the width of the planar type.

Incidentally, it is possible to prevent the dishing in each CMP step by suitably forming the dummy pattern in the region other than the Si-fin layer.

According to the aspect of the present invention involving the use of the dummy gate, it is possible for the dummy gate to be of any construction as far as the dummy gate can be formed by the damascene gate process. Also, in each of the Examples described above, the gate electrode was formed by burying the gate electrode in a gate groove by CMP. Alternatively, it is also possible to form the gate electrode by patterning a conductive layer with a resist used as a mask, followed by applying anisotropic etching such as RIE.

Where the electrode comprises a metal, the metal layer used need not be a single layer. It is also possible to form the metal electrode by mixing and reacting a plurality of metal layers or a plurality of metals. Also, it is possible to form a plurality of different kinds of electrodes on a Single substrate. In the case of a silicon electrode, it is possible for the electrode to contain germanium. When it comes to the gate insulating film, it is possible to use a nitrided oxide film, a dielectric film such as a high-k film and a laminate structure thereof in addition to the thermal oxide film.

According to the embodiments of the present invention, the first and second impurity regions are formed by introducing an impurity into the fin-type silicon layer with the gate electrode (or the dummy gate) used as a mask before and after the step of etching the gate electrode (or the dummy gate) for reducing the size of the gate electrode (or the dummy gate). The particular technique makes it possible to form easily the source drain diffusion regions of a two-layer structure (LDD structure) in the fin-type silicon layer, though it was difficult to form such source drain diffusion regions in the past. As a result, it is possible to obtain a finer fin-type field-effect semiconductor device.

Additional advantages and modifications will readily occur to those skilled in the art. Therefore, the present invention in its broader aspects is not limited to the specific details and representative embodiments shown and described herein. Accordingly, various modifications may be made without departing from the spirit or scope of the general inventive concept as defined by the appended claims and their equivalents.

1.-15. (canceled)

16. A semiconductor device, comprising:
fin silicon layer formed on a semiconductor substrate and having first and second side surfaces;
a mask material formed on the fin silicon layer;
a first gate insulating film and a first gate electrode formed in contact with the first side surface of the fin silicon layer;
a second gate insulating film and a second gate electrode formed in contact with the second side surface of the fin silicon layer;
a third gate electrode formed in contact with upper surfaces of the first gate electrode and the second gate electrode;
first impurity regions formed a prescribed distance apart from a region corresponding to the first, second and third gate electrodes of the fin silicon layer; and
second impurity regions formed between the first impurity regions of the fin silicon layer and the region corresponding to the first, second and third gate electrodes.

17. The semiconductor device according to claim 16, wherein each of the first, second and third gate electrodes comprises a material containing as a main component polycrystalline silicon or amorphous silicon.

18. The semiconductor device according to claim 16, wherein upper surfaces of the first and second gate electrodes are flat, and a width of the third gate electrode is larger than a width of each of the first and second gate electrodes.

19. The semiconductor device according to claim 16, wherein each of the first and second gate electrodes comprises a material containing as a main component polycrystalline silicon or amorphous silicon, and the third gate electrode comprises a metal or a metal silicide.

20. The semiconductor device according to claim 16, wherein each of the first, second and third gate electrodes comprises a material containing as a main component a metal or a metal silicide.

21. The semiconductor device according to claim 16, wherein the upper surfaces of the first and second gate electrodes are flat, and a width of each of the first, second, and the third gate electrodes are the same.

22. The semiconductor device according to claim 16, wherein an impurity concentration in the first impurity regions is higher than that in the second impurity regions.
